(19) United States
(12) Patent Application Publication
(10) Pub. No.: US 2026/0123001 A1
(43) Pub. Date: Apr. 30, 2026

(54) METHOD FOR HORIZONTAL GAP FILLING IN SEMICONDUCTOR MANUFACTURING

(71) Applicant: Tokyo Electron Limited, Tokyo (JP)

(72) Inventors: Yusuke LENT-YOSHIDA, Albany, NY (US); Hunter WILLIAMS, Albany, NY (US); Yun HAN, Albany, NY (US); Yuya WADA, Kurokawa-gun (JP); Shuhei OGAWA, Hillsboro, OR (US)

(73) Assignee: Tokyo Electron Limited, Tokyo (JP)

(21) Appl. No.: 18/929,375

(22) Filed: Oct. 28, 2024

(51) Int. Cl. H01L 29/66; H01L 21/8234; H01L 29/06; H01L 29/08; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 62/151; H10D 64/018; H10D 84/0128; H10D 84/013; H10D 84/038

(57) ABSTRACT

Aspects of the present disclosure provide a method for filling a horizontal gap of a semiconductor structure. For example, the method can include providing a workpiece that includes a stack of alternating first layers and second layers that are parallel with each other. At least one of the second layers can be recessed with respect to vertical sidewalls of two neighboring first layers that sandwich the second layer. A horizontal gap can be formed between the recessed second layer and the two neighboring first layers. The method can further include depositing a gap-filling material to cover the sidewalls of the first layers and fill the horizontal gap, etching back a portion of the gap-filling material that is deposited on the sidewalls of the first layers in an ion bombardment process, and forming a gap filler that includes a remaining portion of the gap-filling material that fills the horizontal gap.

### FIELD OF THE INVENTION

The present disclosure relates to semiconductor manufacturing, and, in particular, to methods for horizontal gap filling in semiconductor manufacturing.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Inner spacer thickness loss caused when etching back inner spacer material (or film) to expose nanowire tips increases parasitic capacitances between gates and source/drain and degrades transistor performance.

### SUMMARY

Aspects of the present disclosure provide a method for filling a horizontal gap of a semiconductor structure. For example, the method can include providing a workpiece that includes a stack of alternating first layers and second layers that are parallel with each other. At least one of the second layers can be recessed with respect to vertical sidewalls of two neighboring first layers that sandwich the second layer, and a horizontal gap can be formed between the recessed second layer and the two neighboring first layers. The method can further include depositing a gap-filling material to cover the sidewalls of the first layers and fill the horizontal gap, etching back a portion of the gap-filling material that is deposited on the sidewalls of the first layers in an ion bombardment process, and forming a gap filler that includes a remaining portion of the gap-filling material that fills the horizontal gap. In an embodiment, two or more than two cycles of depositing the gap-filling material and etching back the portion of the gap-filling material can be executed. In some embodiments, the gap-filling material can include fluorocarbons, hydrofluorocarbons, or silicon oxide based materials.

In an embodiment, the ion bombardment process can include a purely physical etch process. For example, the purely physical etch process can include a sputtering process. As another example, the purely physical etch process can include an ion milling process. In some embodiments, the purely physical etch process can include inert elements. For example, the inert elements can include argon (Ar). As another example, the inert elements can include helium (He).

In another embodiment, the ion bombardment process can include a combination of chemical and physical etch processes. For example, the combination of chemical and physical etch processes can include a reactive ion etching (RIE) process. In an embodiment, the RIE process can include neutral species. In some embodiments, the neural species can include halide chemistries. For example, the halide chemistries can include CₓH_{y}F_{z}, SiClₓ, SiBrₓ or SiFₓ.

In an embodiment, the second layers can be etchable with respect to the first layers. For example, the first layers can include channel layers, and the second layers can include sacrificial layers. As another example, the channel layers and the sacrificial layers can be included in a gate-all-around (GAA) semiconductor structure.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a flow chart of a method of fabricating a semiconductor structure;

FIGS. 2A-2F show the semiconductor structure of FIG. 1 at intermediate steps;

FIG. 3 is a flow chart of a method of fabricating a semiconductor structure according to some embodiments of the present disclosure;

FIGS. 4A and 4B show the semiconductor structure of FIG. 3 at intermediate steps;

FIG. 5 is a flow chart of a method for filling a horizontal gap of a semiconductor structure according to some embodiments of the present disclosure; and

FIGS. 6A-6D show the semiconductor structure of FIG. 5 at intermediate steps.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

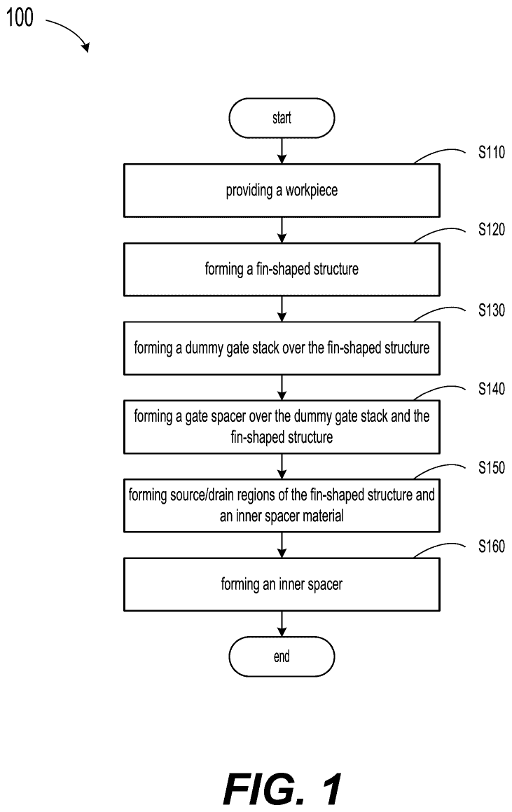

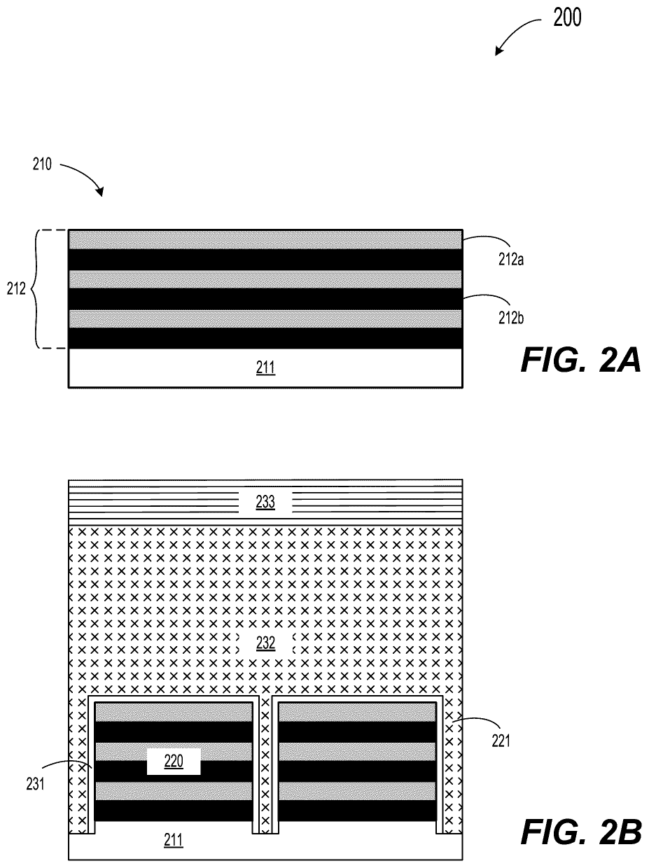

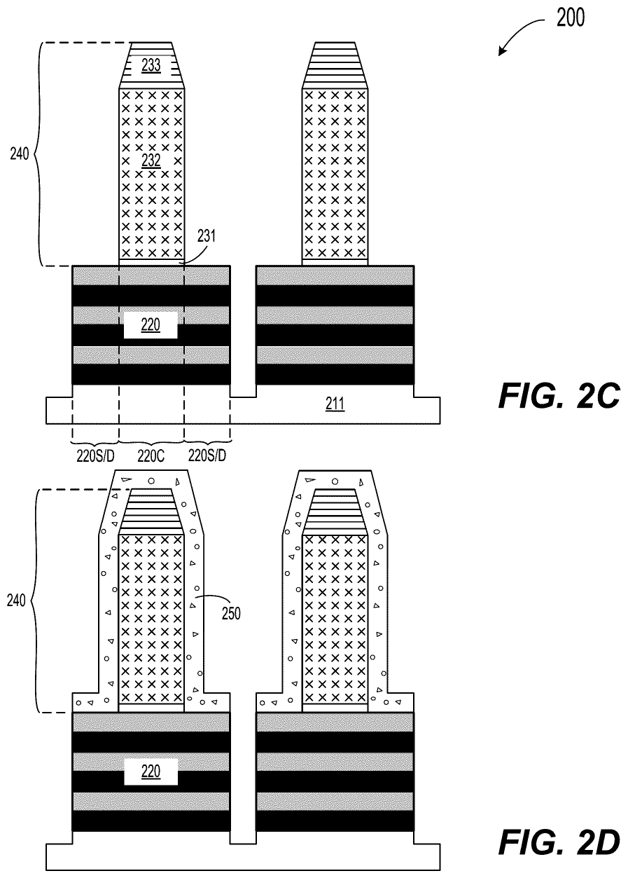

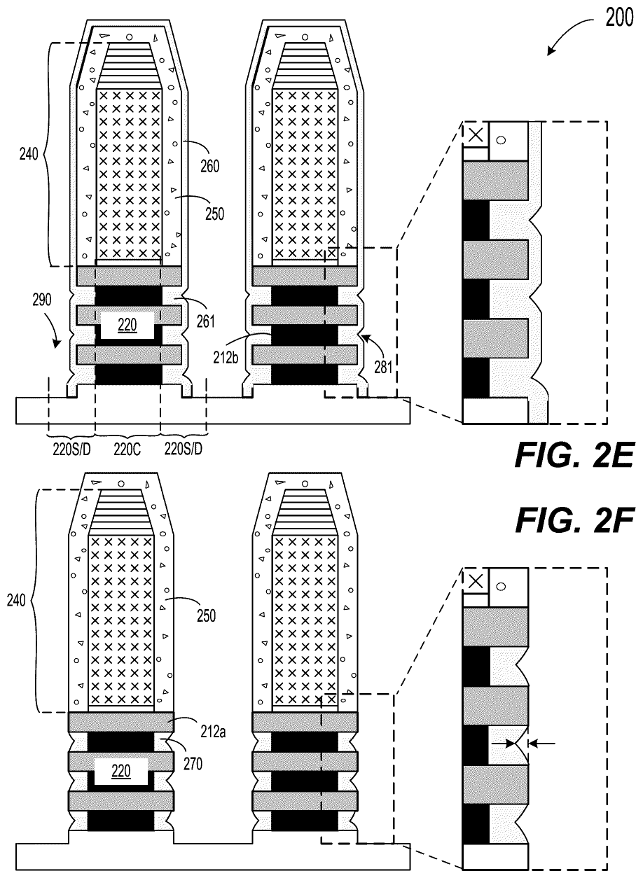

FIG. 1 is a flow chart of a method 100 of fabricating a semiconductor structure (or a semiconductor device) 200. In various embodiments, some of the steps of the method 100 shown can be performed concurrently or in a different order than shown, can be substituted by other method steps, or can be omitted. In some embodiments, additional steps can be provided before, during and after the method 100. Not all steps are described herein in detail for reasons of simplicity. The semiconductor structure 200 can include a semiconductor nano-structure, such as a nanowire structure, a nanosheet structure, etc. FIGS. 2A-2F show the semiconductor structure 200 at intermediate steps.

The method 100 can start with step S110, at which a workpiece 210 is provided, as shown in FIG. 2A. In an embodiment, the workpiece 210 can include a substrate 211 and a stack 212 of alternating semiconductor layers disposed over the substrate 211. The substrate 211 can be a bulk semiconductor substrate, and may include silicon (Si), germanium (Ge), a compound semiconductor (e.g., gallium arsenic (GaAs), indium arsenide (InAs), indium phosphide (InP), silicon carbide (SiC), etc.), or an alloy semiconductor (e.g., silicon germanium (SiGe), silicon germanium carbide (SiGeC), gallium arsenic phosphide (GaAsP), etc.). The substrate 211 can have a silicon-on-insulator (SOI) structure, and may include an oxide layer (e.g., germanium oxide (GeO), germanium-tin oxide (GeSnO), etc.) buried therein.

In an embodiment, the stack 212 can include channel layers 212a and sacrificial layers 212b interleaved with the channel layers 212a. The channel layers 212a may include a first semiconductor composition, e.g., silicon germanium (SiGe), germanium-tin (GeSn), etc. The sacrificial layers 212b may include a second semiconductor composition that is different from the first semiconductor composition such that the sacrificial layers 212b may be selectively etched, recessed and removed relative to the channel layers 212a. For example, the second semiconductor composition may include germanium (Ge). In some embodiments, the sacrificial layers 212b may be doped with boron (B), in order to increase the etch selectivity of the sacrificial layers 212b relative to the channel layers 212a. The channel layers 212a and the sacrificial layers 212b of the stack 212 may be deposited and formed over the substrate 211 in a reduced pressure chemical vapor deposition (RPCVD) process, a molecular beam epitaxy (MBE) process, or other suitable epitaxial growth processes, using different combination of precursors and process temperatures.

The method 100 can proceed to step S120, at which one or more fin-shaped structures 220 are formed from the stack 212, as shown in FIG. 2B. For example, a hard mask layer (not shown) can be deposited and formed over the stack 212 to form an etch mask, and the fin-shaped structures 220 can be patterned and formed from the stack 212 in a lithography process and an etch process. The lithography process can include photoresist coating (e.g., spin-on photoresist coating), soft baking, etch mask aligning, exposure, photoresist developing, rinsing, drying, and other suitable lithography techniques. In the etch process (e.g., dry etch (such as reactive ion etching (RIE)), wet etching, etc.), trenches 221 can be formed that extend through the stack 212 and a portion of the substrate 211 and define the fin-shaped structures 220. In an embodiment, an isolation structure (e.g., a shallow trench isolation (STI) structure) (not shown) may be formed adjacent the fin-shaped structures 220 to isolate the fin-shaped structures 220 from neighboring active regions.

A gate dielectric layer (e.g., including silicon oxide) 231 can be blanketly deposited and formed that covers the fin-shaped structures 220, for example, in a CVD process, an atomic layer deposition (ALD) process, an oxygen plasma oxidation process, etc. A dummy gate layer (e.g., including polysilicon) 232 can then be deposited and formed over the gate dielectric layer 231 to fill the trenches 221, for example, in a CVD process, an ALD process, etc. A gate-top hard mask layer (e.g., including silicon oxide, silicon nitride, etc.) 233 can then be deposited and formed over the dummy gate layer 232 to form an etch mask.

The method 100 can proceed to step S130, at which a dummy gate stack 240 is formed over a channel region 220C of the fin-shaped structure 220, as shown in FIG. 2C. For example, the dummy gate stack 240 can be formed by patterning the gate-top hard mask layer 233, the dummy gate layer 232 and the gate dielectric layer 231 in a lithography process (e.g., photolithography or e-beam lithography). A gate replacement (or gate-last) process can later be performed where the dummy gate stack 240 acts as a placeholder to undergo various processes and is to be removed and replaced by a functional gate structure of the semiconductor structure 200. No dummy gate stack is disposed over source/drain regions 220S/D of the fin-shaped structure 220.

The method 100 can proceed to step S140, at which a gate spacer 250 is formed conformally over the dummy gate stacks 240 and the fin-shaped structures 220 to cover the top surface and sidewalls of each of the dummy gate stacks 240 and the top surface of each of the fin-shaped structures 220, as shown in FIG. 2D. In an embodiment, the gate spacer 250 can be formed in a CVD process, an ALD process, a sub-atmospheric CVD (SACVD) process, etc., and may include silicon carbonitride (SiCN), silicon oxycarbide (SiCN), silicon oxycarbonitride (SiOCN), silicon nitride, etc.

The method 100 can proceed to step S150, at which the source/drain regions 220S/D of the fin-shaped structure 220, which are not covered by the dummy gate stack 240, are recessed to form source/drain trenches 290, as shown in FIG. 2E. In an embodiment, the source/drain regions 220S/D of the fin-shaped structure 220 may be recessed in a dry etch process by implementing a fluorine-containing gas, a chlorine-containing gas, a bromine-containing gas, plasmas, etc., to expose sidewalls of the channel layers 212a and the sacrificial layers 212b of the stack 212.

Also at step S150, an inner spacer material (or film) 260 is formed, as shown in FIG. 2E. For example, the sacrificial layers 212b can be selectively etched and partially removed in a dry etch process or a wet etch process, while the channel layers 212a (which are selectively not etched relative to the sacrificial layers 212b) are substantially unetched, to form inner spacer recesses 261, and the inner spacer material 260 can then be deposited over the fin-shaped structure 220 to cover the top surface and the sidewall of the gate spacer 250 and fill the inner spacer recesses 261. In an embodiment, one or more fluorine-based etchants (e.g., a fluorine gas) may be used in the dry etch process. In another embodiment, hydrogen peroxide or an ammonia hydroxide-hydrogen peroxide-water mixture (APM) may be used in the wet etch process. For example, the inner spacer material 260 may include metal oxide (e.g., aluminum oxide, tantalum oxide, titanium oxide, etc.), silicon-oxide based materials (e.g., silicon oxide, silicon oxycarbonitride (SiOCN), etc.), silicon nitride (SiN), fluorocarbons, hydrofluorocarbons, or a low-k dielectric material. In an embodiment, the inner spacer material 260 may be deposited in a CVD process, a PECVD process, an SACVD process, an ALD process, etc.

The method 100 can proceed to step S160, at which an inner spacer (or, generally, a gap filler) 270 is formed in the inner spacer recesses 261, as shown in FIG. 2F. In an embodiment, the inner spacer material 260 can be etched back and removed from the top surface and the sidewall of the gate spacer 250 and the fin-shaped structure 220 using hydrogen fluoride (HF), fluorine gas (F₂), ammonia (NH₃), nitride trifluoride (NF₃), etc., until revealing the sidewalls (e.g., nanowire tips) of the channel layers 212a of the stack 212. The inner spacer 270 thus formed can be in direct contact with the recessed sacrificial layers 212b and disposed between two neighboring channel layers 212a.

The method 100 can further include additional steps. For example, sources/drains of the semiconductor structure 200 can be formed in the source/drain regions 220S/D by forming (e.g., epitaxially growing) a P+ (or N−) material from an end portion (i.e., the revealed sidewall or nanowire tip) of each of the channel layers 212a in an MBE process, an RPCVD process, a ultra-high vacuum CVD (UHV-CVD) process, or other suitable epitaxial growth processes. As another example, the functional gate structure of the semiconductor structure 200 can be formed by removing the dummy gate stack 240 and the sacrificial layers 212b in a selective dry etch process, a selective wet etch process or a combination thereof relative to the channel layers 212a to uncover (or reveal) the channel layers 212a, and wrapping around each of the uncovered channel layer 212a with a gate dielectric layer (such as a high-k gate dielectric layer, e.g., including hafnium oxide (HfO), titanium oxide (TiO), zirconium oxide (ZrO), etc.) and then a gate electrode layer (e.g., including titanium nitride (TiN), tantalum nitride (TaN), aluminum (Al), tungsten (W), nickel (Ni), etc.) over the gate dielectric layer formed in a CVD process, an ALD process, a PVD process, etc. The semiconductor structure 200 thus formed may be referred to as a gate-all-around (GAA) semiconductor structure 200. A chemical mechanical polishing (CMP) may be performed to remove excessive metal material of the gate electrode layer, thereby providing a substantially planar gate structure.

In the method 100, the inner spacer material 260 deposited at incoming nano-trenches (e.g., nanowire trenches) 281 (shown in FIG. 2E) causes a thickness loss to the inner spacer 270 (indicated by two arrows shown in FIG. 2F) after the inner spacer material 260 is etched back to expose the nanowire tips of the channel layers 212a of the fin-shaped structure 220.

The present disclosure provides a method of fabricating a semiconductor structure by introducing in-situ deposition and etch back cycling to flatten the sidewalls of inner spacers around nanowires. This sidewall flattening can minimize the thickness loss of the inner spacers when the nanowire tips are exposed. According to the present disclosure, area preferential deposition can be combined with a lateral etch back process in one or more chambers to modulate the shape of the inner spacer sidewalls for a horizontal gap filling process. Plasma assisted deposition with controlled bias RF power (and/or frequency, duty-cycle, pressure, platen temperature and gas flows) applied enables the area preferential deposition at the sidewalls of incoming nano-trenches by ion bombardment suppressing deposition growth from other surface area.

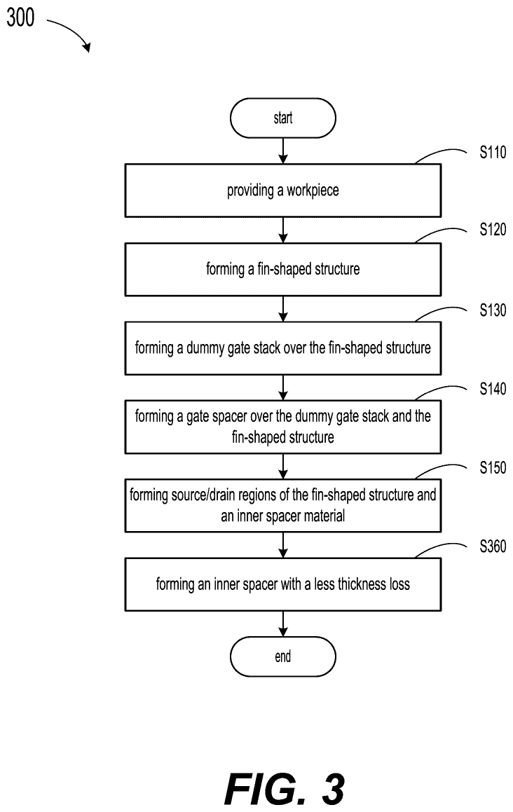

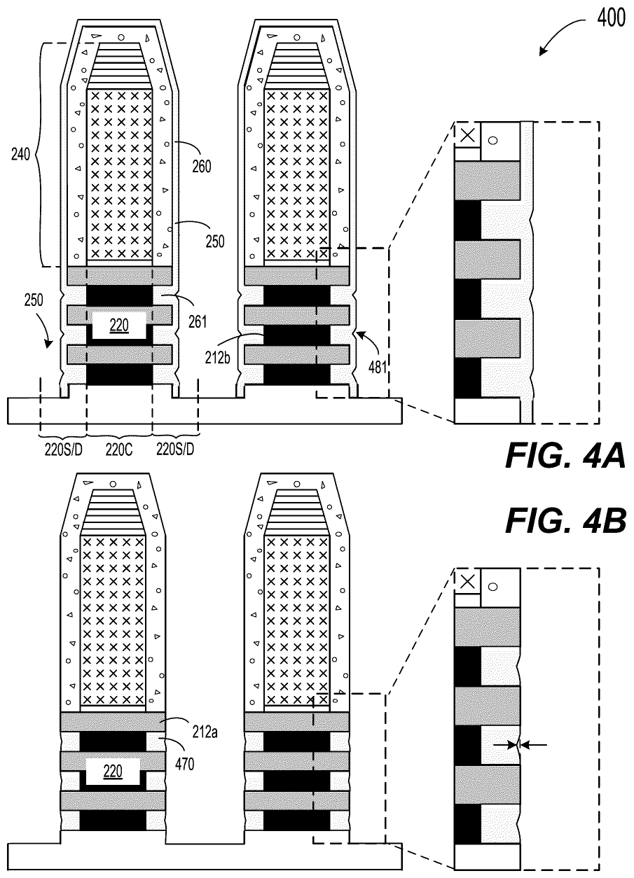

FIG. 3 is a flow chart of a method 300 of fabricating a semiconductor structure (or a semiconductor device) 400 according to some embodiments of the present disclosure. FIGS. 2A-2E, 4A and 4B show the semiconductor structure 400 at intermediate steps. The method 300 is merely an example and is not intended to limit the present disclosure to what is explicitly illustrated in method 300. In various embodiments, some of the steps of the method 300 shown can be performed concurrently or in a different order than shown, can be substituted by other method steps, or can be omitted. In some embodiments, additional steps can be provided before, during and after the method 300. Not all steps are described herein in detail for reasons of simplicity. In the method 300, cyclic process of preferential deposition at incoming sidewall nano-trenches & partial inner spacer etch back can minimize inner spacer thickness loss after revealing nanowire tips. In an embodiment, the preferential deposition at nano-trenches can be achieved by suppressing deposition at non-trench sidewalls due to ion bombardment. In some embodiments, the method 300 can also include steps S110 to S150. The method 300 can then proceed to step S360.

At step S360, an inner spacer (or, generally, a gap filler) 470 is formed in the inner spacer recesses 261, as shown in FIG. 4B. The inner spacer 470 has a less thickness loss (indicated by two arrows shown in FIG. 4B) than the inner spacer 270. In an embodiment, a portion of the inner spacer material 260 that is formed on the sidewalls (e.g., the nanowire tips) of the channel layers 212a of the stack 212 can be etched back in an ion bombardment process, until the sidewalls of the channel layers 212a of the stack 212 are revealed. In a purely physical etch process (e.g., sputtering, ion milling, etc.), atomic positive ions such as inert elements (e.g., argon (Ar), helium (He), etc.) can be created in a plasma, applied with a high energy (e.g., greater than 500 eV), and thus accelerated to anisotropically impact and remove the portion of the inner spacer material 260 that is formed on the sidewalls of the channel layers 212a. In a combination of chemical and physical etch processes (e.g., reactive ion etching (RIE)), a strong electrical field is created in a plasma chamber (e.g., using electrodes in the case of a DC potential or RF excitation, a waveguide in the case of microwaves, etc.) to accelerate free electrons in the plasma chamber to collide with atoms or molecules in the gas phase to produce positive atomic ions (e.g., Ar⁺, He⁺, etc.) and create stable but reactive neutral species (i.e., molecular radicals, such as halide chemistries, e.g., CₓH_{y}F₂, SiClₓ, SiBrₓ, SiFₓ, etc.)), in which the positive atomic ions can be accelerated in another strong electric field to physically impact and remove the portion of the inner spacer material 260 that is formed on the sidewalls of the channel layers 212a and atoms will be ejected into a gas phase to be pumped away by a vacuum system, while the reactive neutral species have chlorine or fluorine atoms, for example, as the active agent to react with the inner spacer material 260 and a volatile gas thus formed can be pumped away.

In the method 300, the inner spacer material 260 deposited at incoming nano-trenches (e.g., nanowire trenches) 481 (shown in FIG. 4A) may also cause a thickness loss to the inner spacer 470 (indicated by two arrows shown in FIG. 4B) after the inner spacer material 260 is etched back to expose the nanowire tips of the channel layers 212a of the fin-shaped structure 220. However, the thickness loss to the inner spacer 470 is less than the thickness loss to the inner spacer 270 as in the method 300 since the deposition is preferentially performed at the inner spacer recesses 261 and less deposition is performed on the sidewalls of the channel layers 212a of the stack 212 due to the ion bombardment. Therefore, the semiconductor structure 400 has decreased parasitic capacitances between the gate structure and sources/drains and improved performance, as compared with the semiconductor structure 200. In some embodiments, more than one cycle of steps S150 (e.g., depositing the inner spacer material 260 at the inner spacer recesses 261) and S360 can be executed.

The method 300 can also include additional steps. For example, sources/drains of the semiconductor structure 400 can be formed in the source/drain regions 220S/D by forming (e.g., epitaxially growing) a P+ (or N−) material from an end portion (i.e., the revealed sidewall or nanowire tip) of each of the channel layers 212a in an MBE process, an RPCVD process, a ultra-high vacuum CVD (UHV-CVD) process, or other suitable epitaxial growth processes. As another example, the functional gate structure of the semiconductor structure 400 can be formed by removing the dummy gate stack 240 and the sacrificial layers 212b in a selective dry etch process, a selective wet etch process or a combination thereof relative to the channel layers 212a to uncover (or reveal) the channel layers 212a, and wrapping around each of the uncovered channel layer 212a with a gate dielectric layer (such as a high-k gate dielectric layer, e.g., including HfO, TiO, ZrO, etc.) and then a gate electrode layer (e.g., including TIN, TaN, Al, W, Ni, etc.) over the gate dielectric layer formed in a CVD process, an ALD process, a PVD process, etc. The semiconductor structure 400 thus formed may be referred to as a GAA semiconductor structure 400. A CMP may be performed to remove excessive metal material of the gate electrode layer, thereby providing a substantially planar gate structure.

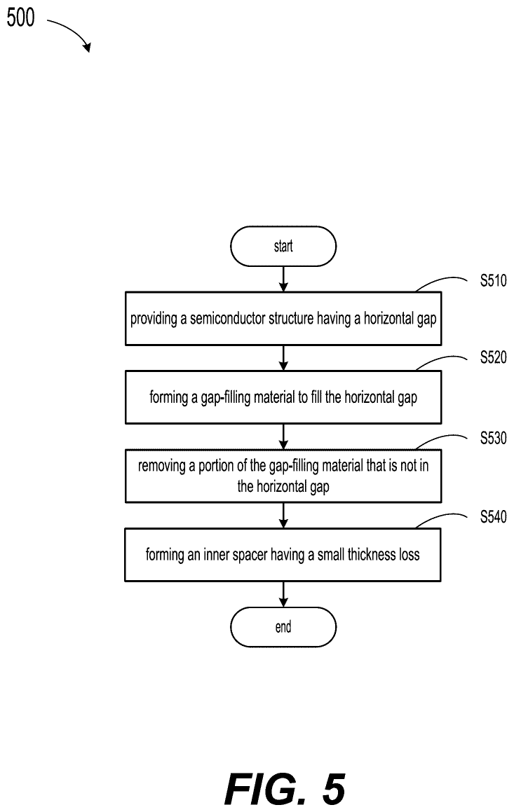

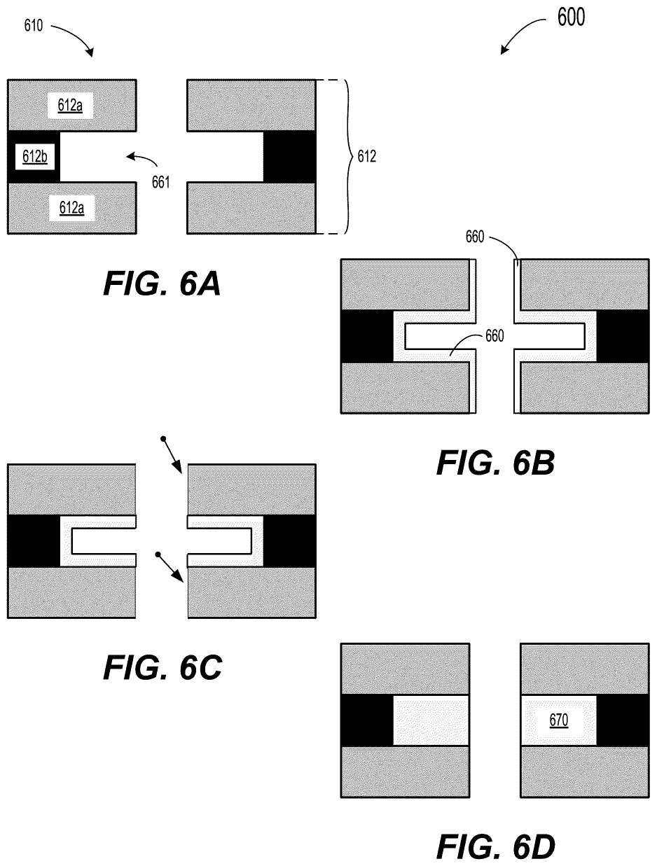

FIG. 5 is a flow chart of a method 500 for filling a horizontal gap of a semiconductor structure (or a semiconductor device) 600 according to some embodiments of the present disclosure. FIGS. 6A-6D show the semiconductor structure 600 at intermediate steps. The method 500 is merely an example and is not intended to limit the present disclosure to what is explicitly illustrated in method 500. In various embodiments, some of the steps of the method 500 shown can be performed concurrently or in a different order than shown, can be substituted by other method steps, or can be omitted. In some embodiments, additional steps can be provided before, during and after the method 500. Not all steps are described herein in detail for reasons of simplicity.

The method 500 can start with step 510, at which a semiconductor structure 600 is provided that includes a horizonal gap to be filled with a gap-filling material, as shown in FIG. 6A. In an embodiment, the semiconductor structure 600 can include a workpiece 610 (e.g., the workpiece 210) that includes a stack 612 of alternating semiconductor layers disposed in parallel with each other over a substrate (not shown). For example, the stack 612 can include channel (or first) layers 612a (e.g., the channel layers 212a) and sacrificial (or second) layers 612b (e.g., the sacrificial layers 212b) interleaved with the channel layers 612a. In an embodiment, at least one of the sacrificial layers 612b is recessed with respect to vertical sidewalls of two neighboring channel layers 621a that sandwich the recessed sacrificial layer 612b, and a horizontal gap (or a cavity) 661 (e.g., the inner spacer recess 261) is thus formed between the recessed sacrificial layer 612b and the two neighboring channel layers 621a.

The method 500 can proceed to step S520, at which a gap-filling material 660 (e.g., the inner spacer material 260) is deposited and formed to cover the sidewalls of the channel layers 612a and fill the horizontal gap 661, as shown in FIG. 6B. For example, metal oxide (e.g., aluminum oxide, tantalum oxide, titanium oxide, etc.), silicon-oxide based materials (e.g., silicon oxide, silicon oxycarbonitride (SiOCN), etc.), silicon nitride (SiN), fluorocarbons, hydrofluorocarbons, or a low-k dielectric material may be deposited and formed to fill the horizontal gap 661 and the sidewalls of the channel layers 612a in a CVD process, a PECVD process, an SACVD process, an ALD process, etc.

The method 500 can proceed to step S530, at which a portion of the gap-filling material 660 that is formed on the sidewalls of the channel layers 612a of the stack 612 is removed. For example, the portion of the gap-filling material 660 that is formed on the sidewalls of the channel layers 612a of the stack 612 can be etched back in an ion bombardment process (indicated by arrows), until the sidewalls of the channel layers 612a of the stack 612 are revealed, as shown in FIG. 6C. Accordingly, more gap-filling material 660 can be deposited in the horizontal gap 661, and less gap-filling material 660 will be deposited on the sidewalls of the channel layers 612a due to the ion bombardment. In a purely physical etch process (e.g., sputtering, ion milling, etc.), atomic positive ions such as inert elements (e.g., Ar, He, etc.) can be created in a plasma, applied with a high energy (e.g., greater than 500 eV), and thus accelerated to anisotropically impact and remove the portion of the gap-filling material 660 that is formed on the sidewalls of the channel layers 612a. In a combination of chemical and physical etch processes (e.g., reactive ion etching (RIE)), a strong electrical field is created in a plasma chamber (e.g., using electrodes in the case of a DC potential or RF excitation, a waveguide in the case of microwaves, etc.) to accelerate free electrons in the plasma chamber to collide with atoms or molecules in the gas phase to produce positive atomic ions (e.g., Ar⁺, He⁺, etc.) and create stable but reactive neutral species (i.e., molecular radicals, such as halide chemistries, e.g., CₓH_{y}F₂, SiClₓ, SiBrₓ, SiFₓ, etc.)), in which the positive atomic ions can be accelerated in another strong electric field to physically impact and remove the portion of the gap-filling material 660 that is formed on the sidewalls of the channel layers 612a and atoms will be ejected into a gas phase to be pumped away by a vacuum system, while the reactive neutral species have chlorine or fluorine atoms, for example, as the active agent to react with the gap-filling material 660 and a volatile gas thus formed can be pumped away.

In some embodiments, more than one cycle of steps S520 (e.g., depositing the gap-filling material 660 at the horizontal gap 661) and S530 (e.g., removing the portion of the gap-filling material 660 that is formed on the sidewalls of the channel layers 612a) can be executed.

The method 500 can proceed to step S540, at which the portion of the gap-filling material 660 that is formed on the sidewalls of the channel layers 612a of the stack 612 is removed and the horizontal gap 661 is fully filled with the gap-filling material 660, after one or more cycles of steps S520 and S530 are executed. Accordingly, an inner spacer (or, generally, a gap filler) 670 is formed in the horizontal gap 661 that fully fills the horizontal gap 661 and has a small inner spacer thickness loss.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for filling a horizontal gap of a semiconductor structure, comprising:
providing a workpiece, the workpiece including a stack of alternating first layers and second layers that are parallel with each other, at least one of the second layers being recessed with respect to vertical sidewalls of two neighboring first layers that sandwich the second layer, a horizontal gap being formed between the recessed second layer and the two neighboring first layers;
depositing a gap-filling material to cover the sidewalls of the first layers and fill the horizontal gap;
etching back a portion of the gap-filling material that is deposited on the sidewalls of the first layers in an ion bombardment process; and
forming a gap filler that includes a remaining portion of the gap-filling material that fills the horizontal gap.

2. The method of claim 1, wherein two or more than two cycles of depositing the gap-filling material and etching back the portion of the gap-filling material are executed.

3. The method of claim 1, wherein the ion bombardment process includes a purely physical etch process.

4. The method of claim 3, wherein the purely physical etch process includes a sputtering process.

5. The method of claim 3, wherein the purely physical etch process includes an ion milling process.

6. The method of claim 3, wherein the purely physical etch process includes inert elements.

7. The method of claim 6, wherein the inert elements include argon (Ar).

8. The method of claim 6, wherein the inert elements include helium (He).

9. The method of claim 1, wherein the ion bombardment process includes a combination of chemical and physical etch processes.

10. The method of claim 9, wherein the combination of chemical and physical etch processes includes a reactive ion etching (RIE) process.

11. The method of claim 10, wherein the RIE process includes neutral species.

12. The method of claim 11, wherein the neutral species includes halide chemistries.

13. The method of claim 12, wherein the halide chemistries include CₓH_{y}F_{z}.

14. The method of claim 12, wherein the halide chemistries include SiClₓ.

15. The method of claim 12, wherein the halide chemistries include SiBrₓ.

16. The method of claim 12, wherein the halide chemistries include SiFₓ.

17. The method of claim 1, wherein the second layers are etchable with respect to the first layers.

18. The method of claim 17, wherein the first layers include channel layers, and the second layers include sacrificial layers.

19. The method of claim 18, wherein the channel layers and the sacrificial layers are included in a gate-all-around (GAA) semiconductor structure.

20. The method of claim 1, wherein the gap-filling material includes fluorocarbons, hydrofluorocarbons, or silicon oxide based materials.
